(19) United States
(12) Patent Application Publication
(10) Pub. No.: US 2019/0280103 A1
(43) Pub. Date: Sep. 12, 2019

(54) SEMICONDUCTOR STRUCTURE AND METHOD FOR MANUFACTURING THE SAME

(71) Applicant: MACRONIX INTERNATIONAL CO., LTD., Hsinchu (TW)

(72) Inventors: Sheng-Hong CHEN, Kaohsiung City (TW); Ting-Feng LIAO, New Taipei City (TW)

(21) Appl. No.: 15/916,455

(22) Filed: Mar. 9, 2018

(51) Int. Cl. H01L 29/66; H01L 27/24; H01L 29/06; H01L 21/02; H01L 21/8239; H01L 23/00

(52) U.S. Cl. CPC H01L 29/66545; H01L 27/249; H01L 24/06; H01L 21/02507; H01L 21/8239; H01L 29/0649

(57) ABSTRACT

A semiconductor structure includes a substrate including a dummy area and an array area adjacent to the dummy area, sub-dummy structures, sub-array structures, a three-dimensional array of memory cells, first conductive structures and second conductive structures. The sub-dummy structures are disposed on the dummy area, and separated from each other by first trenches extending along a first direction. The sub-array structures are disposed on the array area, and separated from each other by second trenches extending along a second direction. The memory cells include cell groups disposed in the sub-array structures, respectively. The first conductive structures and the second conductive structures are disposed in the first trenches and the second trenches respectively. Each of the first conductive structures extends along the first direction, each of the second conductive structure extends along the second direction, and the first direction is different from the second direction.

### TECHNICAL FIELD

This disclosure relates to a semiconductor structure and a method for manufacturing the same. More particularly, this disclosure relates to a semiconductor structure comprising memory cells and a method for manufacturing the same.

### BACKGROUND

For reasons of decreasing volume and weight, increasing power density, improving portability and the like, three-dimensional (3-D) semiconductor structures have been developed. In addition, elements and spaces in a semiconductor device have continuously been shrunk. This may cause some problems. For example, in a manufacturing process for a 3-D memory device, stacks having a high aspect ratio may be formed for the construction of memory cells and/or other components. Such a stack may bend or collapse due to its high aspect ratio. As such, various improvements for the semiconductor structures and the methods for manufacturing them are still desired.

### SUMMARY

This disclosure is directed to semiconductor structures and methods for manufacturing the same, and particularly to a semiconductor structure comprising memory cells and a method for manufacturing the same.

According to some embodiments, a semiconductor structure comprises a substrate, a plurality of sub-dummy structures, a plurality of sub-array structures, a three-dimensional array of memory cells, a plurality of first conductive structures and a plurality of second conductive structures. The substrate comprises a dummy area and an array area adjacent to the dummy area. The sub-dummy structures are disposed on the dummy area. The sub-dummy structures are separated from each other by a plurality of first trenches. Each of the first trenches extends along a first direction. The sub-array structures are disposed on the array area. The sub-array structures are separated from each other by a plurality of second trenches. Each of the second trenches extends along a second direction. The memory cells comprise a plurality of cell groups disposed in the sub-array structures, respectively. The first conductive structures and the second conductive structures are disposed in the first trenches and the second trenches respectively. Each of the first conductive structures extends along the first direction, each of the second conductive structure extends along the second direction, and the first direction is different from the second direction.

According to some embodiments, a method for manufacturing a semiconductor structure comprises the following steps. First, an initial structure is provided. The initial structure comprises a substrate and a preliminary array structure formed on the substrate. The substrate comprises a dummy area and an array area. The preliminary array structure comprises a stack and a plurality of active structures penetrating through the stack. Each of the active structures comprises a channel layer and a memory layer formed between the channel layer and the stack. Next, a plurality of first trenches extending along a first direction at first predetermined trench positions are formed in the preliminary array structure for separating the preliminary array structure on the dummy area into a plurality of sub-dummy structures. A plurality of second trenches extending along a second direction at second predetermined trench positions are formed in the preliminary array structure for separating the preliminary array structure on the array area into a plurality of sub-array structures. Then, a plurality of first conductive structures and a plurality of second conductive structures are formed in the first trenches and the second trenches, respectively. Each of the first conductive structures extends along the first direction, each of the second conductive structure extends along the second direction, and the first direction is different from the second direction.

### BRIEF DESCRIPTION OF THE DRAWINGS

FIGS. 1A-1C illustrate a semiconductor structure according to embodiments.

FIGS. 2A-9C illustrate a method for manufacturing a semiconductor structure according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The accompanying drawings are provided for illustrative and explaining purposes rather than a limiting purpose. For clarity, the elements may not be drawn to scale. In addition, some components and/or reference numerals may be omitted from some drawings. It is contemplated that the elements and features of one embodiment can be beneficially incorporated in another embodiment without further recitation.

A semiconductor structure according to embodiments comprises a substrate, a plurality of sub-dummy structures, a plurality of sub-array structures, a three-dimensional array of memory cells, a plurality of first conductive structures and a plurality of second conductive structures. The substrate comprises a dummy area and an array area adjacent to the dummy area. The sub-dummy structures are disposed on the dummy area. The sub-dummy structures are separated from each other by a plurality of first trenches. Each of the first trenches extends along a first direction. The sub-array structures are disposed on the array area. The sub-array structures are separated from each other by a plurality of second trenches. Each of the second trenches extends along a second direction. The memory cells comprise a plurality of cell groups disposed in the sub-array structures, respectively. The first conductive structures and the second conductive structures are disposed in the first trenches and the second trenches respectively. Each of the first conductive structures extends along the first direction, each of the second conductive structure extends along the second direction, and the first direction is different from the second direction.

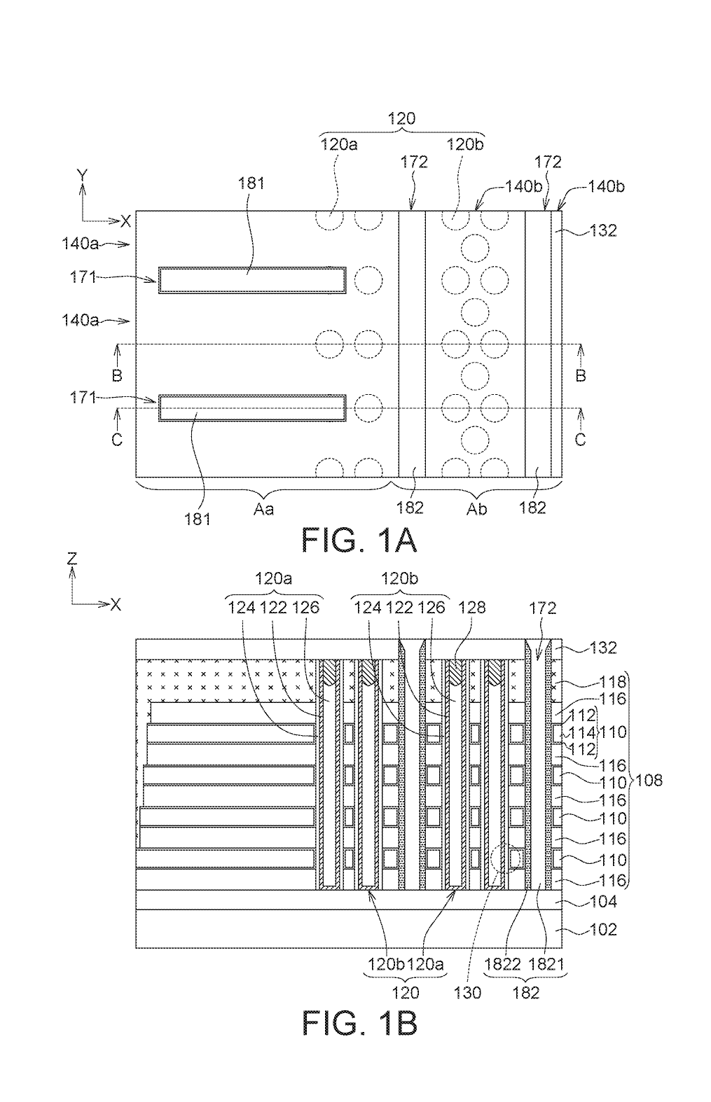

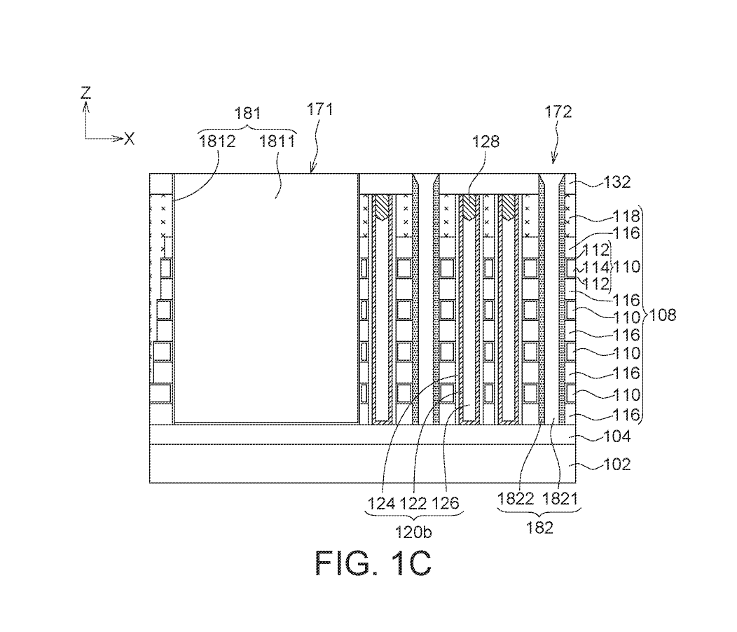

Referring to FIGS. 1A-1C, such a semiconductor structure is shown. In the accompanying drawings, for ease of understanding, the semiconductor structure is illustrated as a 3-D vertical channel NAND memory structure.

The semiconductor structure comprises a substrate 102. The substrate 102 may comprise structures, components, and the like formed therein and/or thereon. For example, the substrate 102 may comprise a buried layer 104 disposed thereon. The substrate 102 comprises a dummy area Aa and an array area Ab adjacent to the dummy area Aa.

The semiconductor structure comprises a plurality of sub-dummy structures 140a and a plurality of sub-array structures 140b. The sub-dummy structures 140a are disposed on the dummy area Aa of the substrate 102, and the sub-array structures 140b are disposed on the array area Ab of the substrate 102. The sub-dummy structures 140a are separated from each other by a plurality of first trenches 171. Each of the first trenches 171 extends along a first direction. The sub-array structures 140b are separated from each other by a plurality of second trenches 172. Each of the second trenches 172 extends along a second direction. The first direction is different from the second direction.

In a comparison embodiment which has no dummy area or has a dummy area without a trench extending along a direction different from that of a trench in the array area, a stress toward the array area may cause a structure in the array area bended after a thermal process. In the present application, since the first trenches 171 extend along the direction different from the extending direction of the second trenches 172, the stress toward the array area Ab after implementing a thermal process can be released and balanced in the dummy area Aa by the first trenches 171, the high level of stress accumulated at the boundary between the dummy area Aa and the array area Ab can be avoided, less stress may affect the physical structure of the semiconductor structure, the bending problem of the structure on the array area, such as the bending of a common source line, can be solved.

In the present embodiment, the first direction may be perpendicular to the second direction, for example, the first direction may be the X-direction in the drawing, and the second direction may be the Y-direction in the drawings. In other embodiments, the first direction and the second direction may not be perpendicular to each other. FIGS. 1A-1C exemplarily illustrate a portion of the dummy area Aa and the array area Ab, more sub-dummy structures 140a and more sub-array structures 140b may be disposed on the substrate 102.

In the present embodiment, each of the first trenches 171 and the second trenches 172 has a bar-shaped structure. In other embodiments, each of the first trenches 171 and the second trenches 172 may have other kind of shapes.

According to some embodiments, the semiconductor structure may comprise a stack 108 and one or more active structures 120 penetrating through the stack 108. The active structures 120 comprises first active structures 120a and second active structures 120b disposed on the dummy area Aa and the array area Ab, respectively. While FIG. 1B illustrates the example that each cell group comprises two rows of the active structures 120 (i.e. first active structures 120a and second active structures 120b), the embodiments are not limited thereto. The stack 108 comprises alternately stacked conductive layers 110 and insulating layers 116. In some embodiments, each conductive layer 110 comprises two high-k dielectric layers 112 and a conductive core layer 114 disposed therebetween, as shown in FIGS. 1B-1C. In such cases, the conductive core layer 114 may be formed of a metal material. The two high-k dielectric layers 112 may be connected with each other. In some other embodiments, each conductive layer 110 may be composed of a single layer. In such cases, the conductive core layer 114 may be formed of doped-polysilicon. In some embodiments, the stack 108 further comprises a hard mask layer 118 disposed on the conductive layers 110 and the insulating layers 116. According to some embodiments, each active structure 120 may be formed in a column-type configuration. In such cases, each active structure 120 may comprise a channel layer 122 and a memory layer 124 disposed between the channel layer 122 and the stack 108. In some embodiments, each active structure 120 further comprises an insulating material 126 filled in a space formed by the channel layer 122. In some embodiments, each sub-dummy structure 140a and each sub-array structure 140b further comprise one or more conductive pads 128 coupled to the one or more active structures 120, respectively. In some embodiments, each sub-dummy structure 140a and each sub-array structure 140b further comprises an interlayer dielectric layer 132 disposed on the stack 108. According to some embodiments, the sub-dummy structures 140a and the sub-array structures 140b may have a high aspect ratio.

The semiconductor structure comprises a plurality of first conductive structures 181 and a plurality of second conductive structures 182 disposed in the first trenches 171 and the second trenches 172, respectively. Each of the first conductive structures 181 extends along the first direction (the X-direction in the drawings), and each of the second conductive structures 182 extends along the second direction (the Y-direction in the drawings). Each of the first conductive structures 181 comprises a conductive filling portion 1811 and a high-k dielectric layer 1812 surrounding the conductive filling portion 1811. Each of the second conductive structures 182 comprises a conductive center portion 1821 and an insulating liner layer 1822 surrounding the conductive center portion 1821.

The semiconductor structure comprises a three-dimensional array of memory cells 130. The memory cells 130 comprise a plurality of cell groups (not indicated in the drawings) disposed in the sub-array structures 140b, respectively. More specifically, the memory cells 130 in the cell group disposed in the each sub-array structure 140b can be defined by cross points between the conductive layers 110 of the stack 108 and the one or more active structures 120. According to some embodiments, the conductive layers 110 of the sub-array structures 140b may be configured for word lines, the conductive pads 128 of the sub-array structures 140 may be configured for bit lines, and the conductive center portions 1821 may be configured for common source lines.

According to some embodiments, the distribution and the amount of the active structures 120 may be different in the dummy area Aa and the array area Ab. The first active structures 120a may have a first density in the dummy area Aa, the second active structures 120b may have a second density in the array area Ab, and the first density is smaller than the second density.

Now the description is directed to a method for manufacturing a semiconductor structure according to embodiments. It comprises the following steps. First, an initial structure is provided. The initial structure comprises a substrate and a preliminary array structure formed on the substrate. The substrate comprises a dummy area and an array area. The preliminary array structure comprises a stack and a plurality of active structures penetrating through the stack. Each of the active structures comprises a channel layer and a memory layer formed between the channel layer and the stack. Next, a plurality of first trenches extending along a first direction at first predetermined trench positions is formed in the preliminary array structure for separating the preliminary array structure on the dummy area into a plurality of sub-dummy structures. A plurality of second trenches extending along a second direction at second predetermined trench positions is formed in the preliminary array structure for separating the preliminary array structure on the array area into a plurality of sub-array structures. Then, a plurality of first conductive structures and a plurality of second conductive structures are formed in the first trenches and the second trenches, respectively. Each of the first conductive structures extends along the first direction, each of the second conductive structure extends along the second direction, and the first direction is different from the second direction.

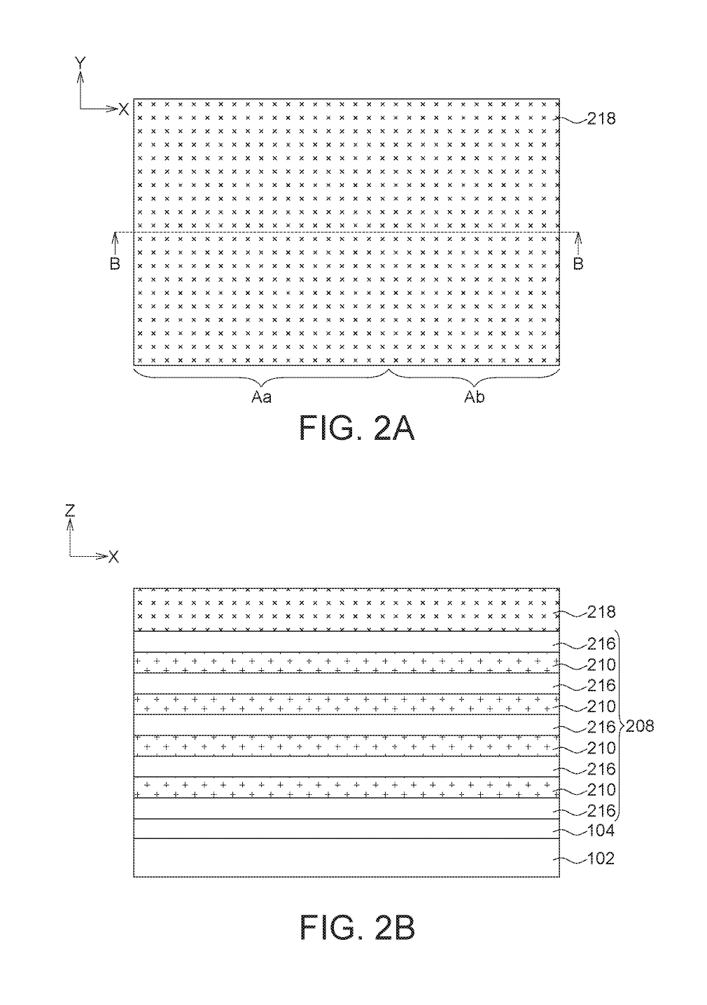

Referring to FIGS. 2A-9C, such a method is illustrated. For ease of understanding, the method is illustrated to form the semiconductor structure as shown in FIGS. 1A-1C applying a process using sacrificial layers, which will be replaced with conductive layers in the following steps. The figures identified by “B” and “C” show cross-sections taken along the line B-B and the line C-C in the figures identified “A”, respectively.

As shown in FIGS. 2A-2B, a substrate 102 is provided. The substrate 102 comprises a dummy area Aa and an array area Ab adjacent to the dummy area Aa. The substrate 102 may comprise structures, components, and the like formed therein and/or thereon. For example, the substrate 102 may comprise a buried layer 104 disposed thereon, as shown in FIG. 2B. The buried layer 104 may be formed of oxide. A stack 208 is formed on the substrate 102. The stack 208 comprises alternately stacked sacrificial layers 210 and insulating layers 216. The sacrificial layers 210 may be formed of silicon nitride (SiN). The insulating layers 216 may be formed of oxide. In some embodiments, as shown in FIGS. 2A-2B, the stack 208 further comprises a hard mask layer 218 formed on the sacrificial layers 210 and the insulating layers 216, which is used to compensate the film stress and prevent the stack collapse or bending.

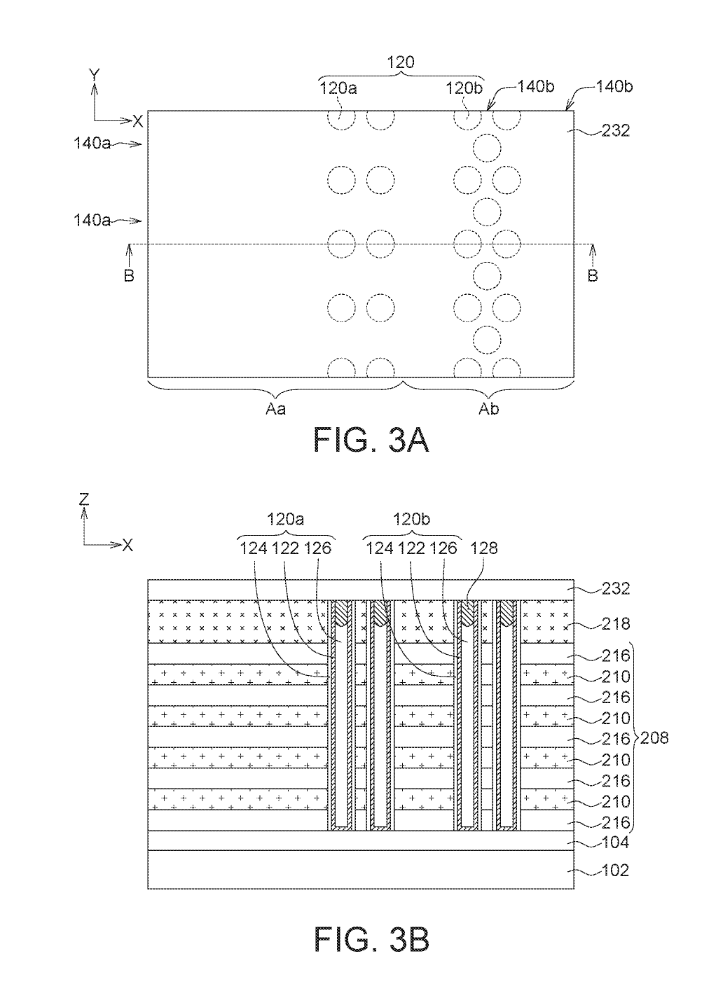

As shown in FIGS. 3A-3B, a plurality of active structures 120 are formed through the stack 208. The active structures 120 comprises first active structures 120a and second active structures 120b disposed on the dummy area Aa and the array area Ab, respectively. More specifically, in some embodiments, a plurality of holes may be formed through the stack 208. A plurality of memory layers 124 may be formed on sidewalls of the holes, respectively. The memory layers 124 may have multi-layer structures, such as ONO (oxide/nitride/oxide,), ONONO (oxide/nitride/oxide/nitride/oxide) or the like. A plurality of channel layers 122 may be formed on the memory layers 124, respectively. The channel layers 122 may be also formed on bottoms of the holes. The channel layers 122 may be formed of polysilicon. An insulating material 126 may be filled into remaining spaces of the holes. In some embodiments, a plurality of conductive pads 128 are formed on the insulating material 126 in the holes. Each of them is coupled to the corresponding active structure 120, particularly to the channel layer 122 thereof. Then, an interlayer dielectric layer 232 may be formed on the stack 208 and the active structures 120.

As such, said “initial structure” is formed. The initial structure comprises a substrate 102 and a preliminary array structure formed on the substrate 102, wherein the preliminary array structure comprises a plurality of sub-dummy structures 140a and a plurality of sub-array structures 140b that will be separated in the following steps. The preliminary array structure comprises a stack 208 and a plurality of active structures 120 penetrating through the stack 108. Each active structure 120 comprises a channel layer 122 and a memory layer 124 formed between the channel layer 122 and the stack 208. In some embodiments, the preliminary array structure further comprises a plurality of conductive pads 128 coupled to the active structures 120, respectively. In some embodiments, the preliminary array structure further comprises an interlayer dielectric layer 232 formed on the stack 208.

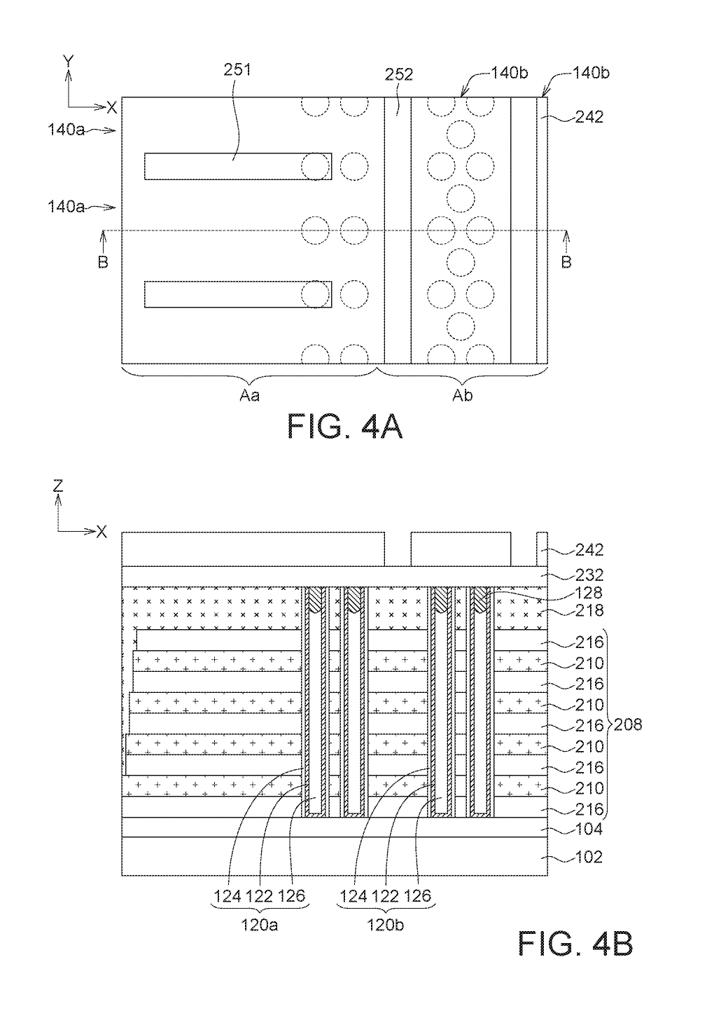

As shown in FIGS. 4A-4B, a photo resist layer 242 is formed on the interlayer dielectric layer 232. The photo resist layer 242 comprises apertures to define first predetermined trench positions 251 and second predetermined trench positions 252. The first predetermined trench positions 251 correspond to the first trenches 171 configured for separating the preliminary array structure on the dummy area Aa into sub-dummy structures 140a. The second predetermined trench positions 252 correspond to the second trenches 172 configured for separating the preliminary array structure on the array area Ab into sub-array structures 140b.

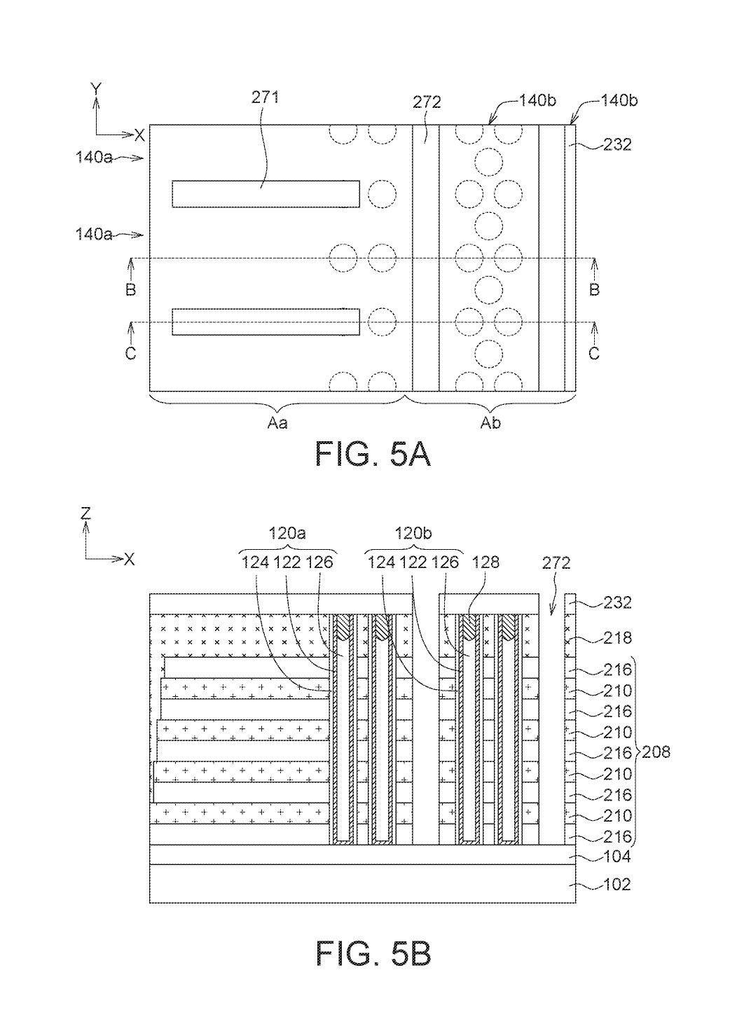

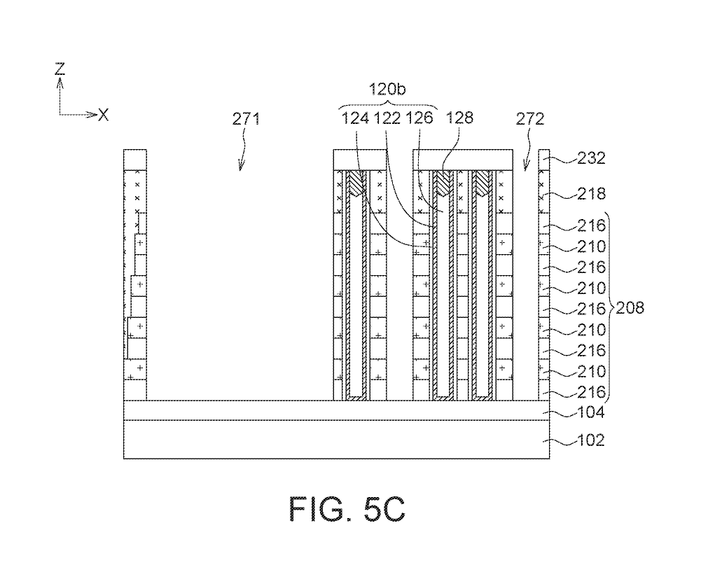

As shown in FIGS. 5A-5C, a plurality of first openings 271 and second openings 272 are formed at the first predetermined trench positions 251 and the second predetermined trench positions 252, respectively, for example by an etching process. The first openings 271 and the second openings 272 expose the buried layer 104. Then, the photo resist layer 242 is removed.

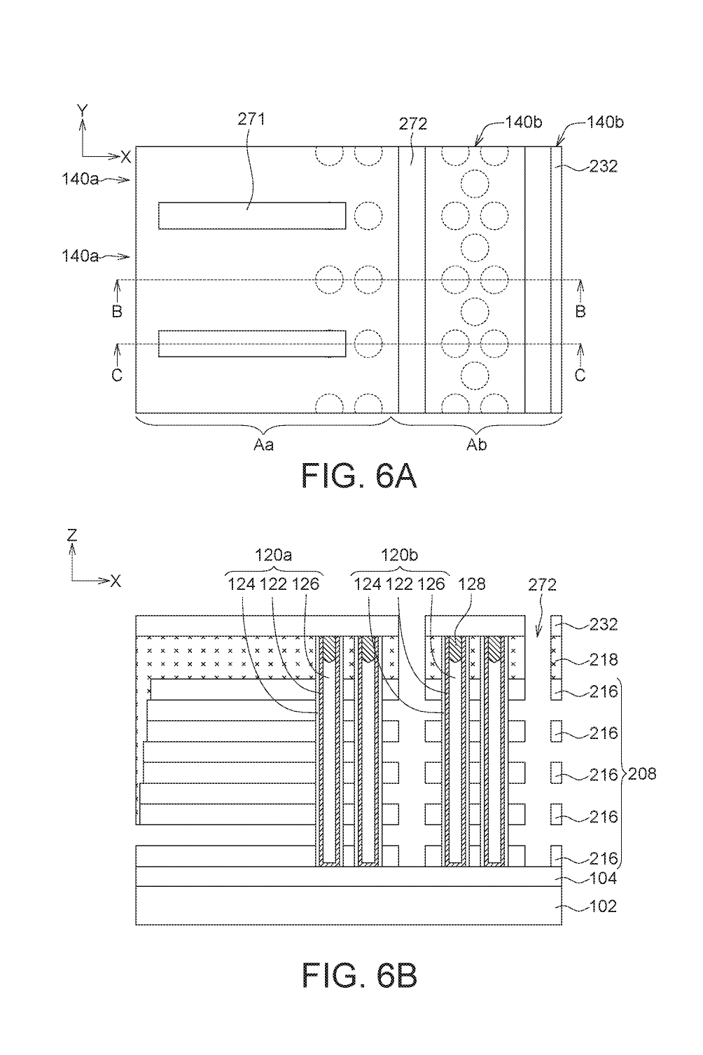

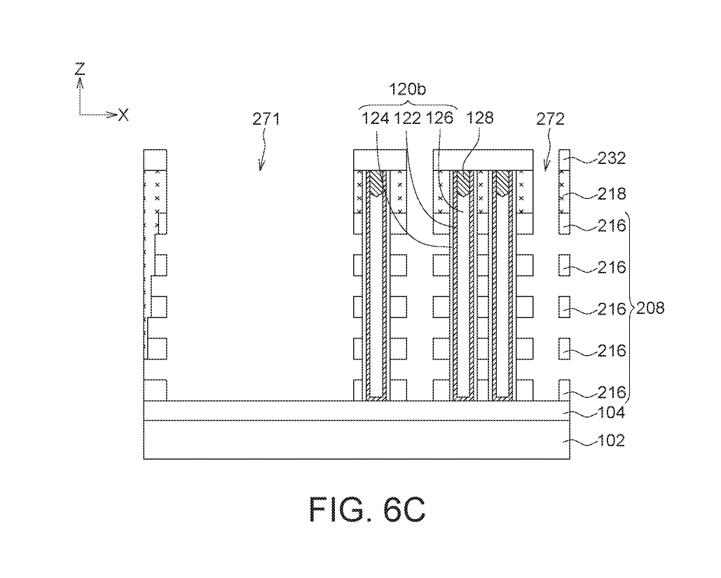

As shown in FIGS. 6A-6C, the sacrificial layers 210 are removed through the first openings 271 and the second openings 272, such as by an etching process using hot phosphoric acid (HF).

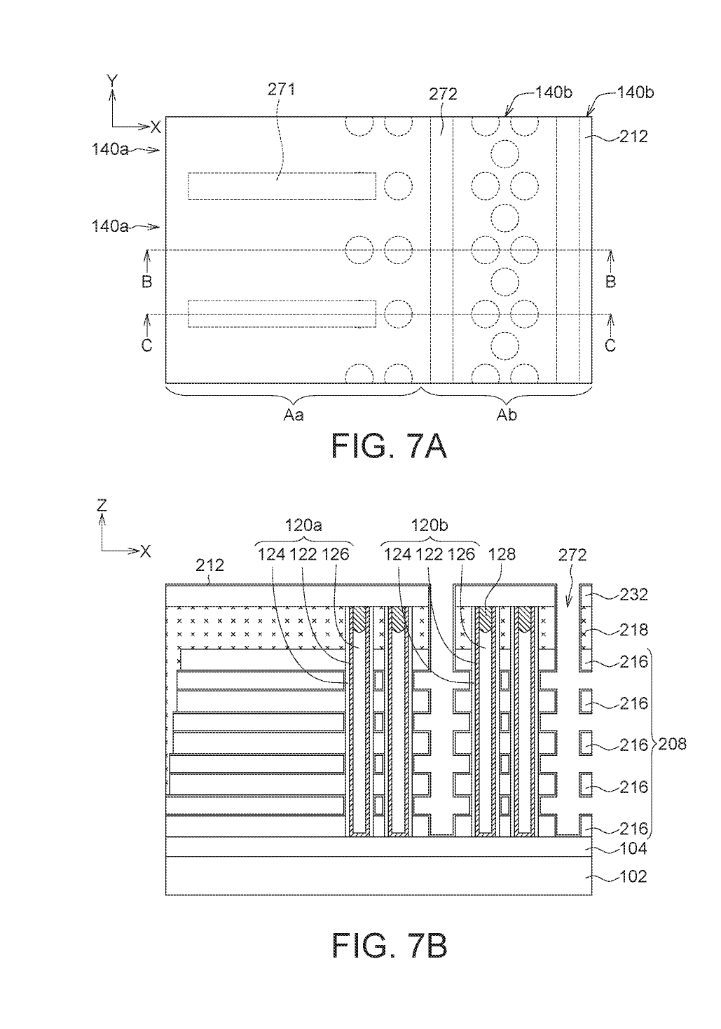

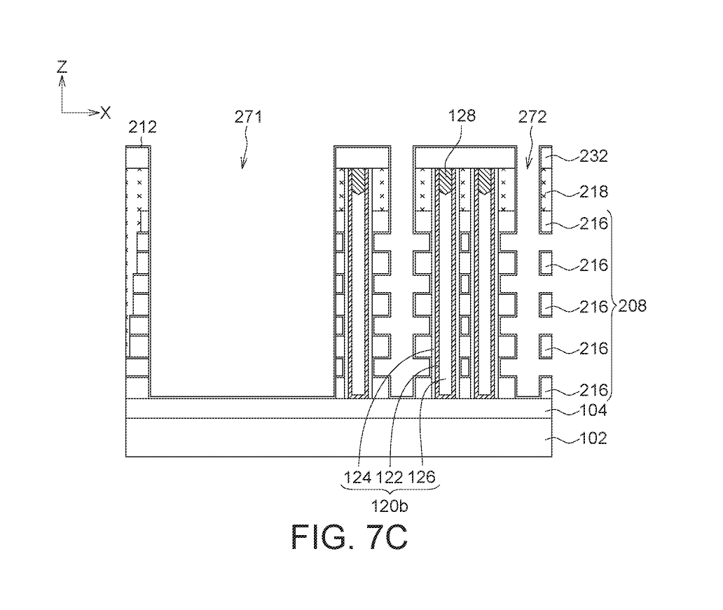

As shown in FIGS. 7A-7C, high-k dielectric layers 212 are formed on top sides and bottom sides of the insulating layers 216, in the first openings 271 and the second openings 272, and on top of the interlayer dielectric layer 232. For example, a high-k dielectric material may be formed on the structure of FIGS. 6A-6C in a conformal manner, as shown in FIGS. 7A-7C. The high-k dielectric material may be Al₂O₃ or the like.

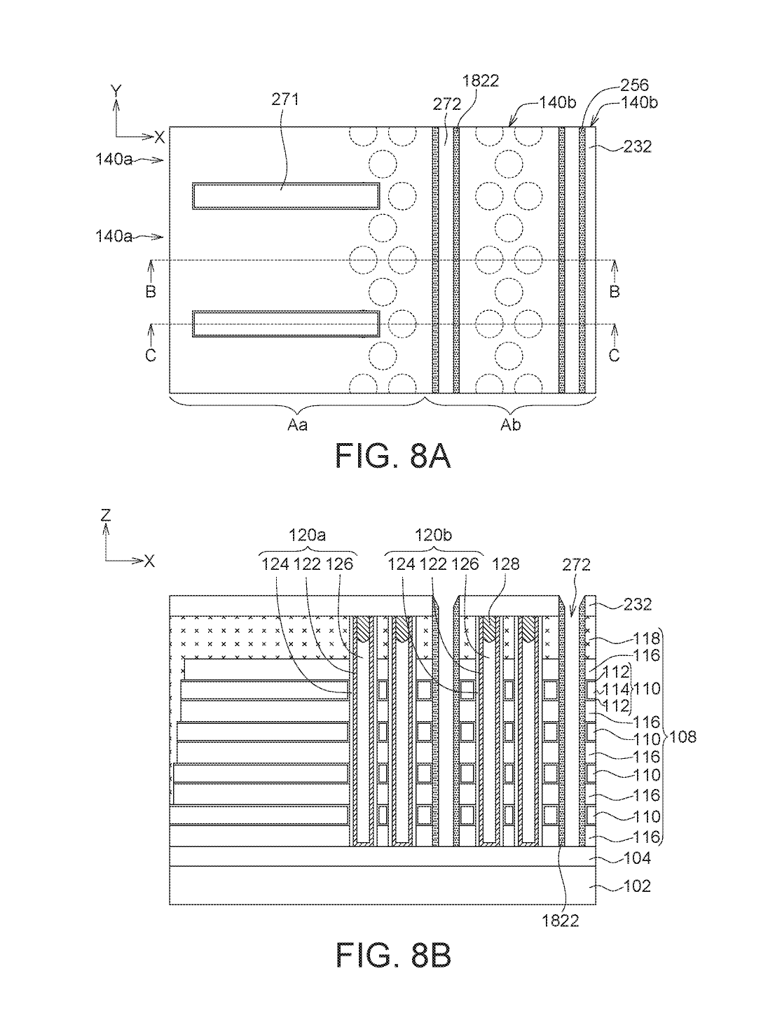

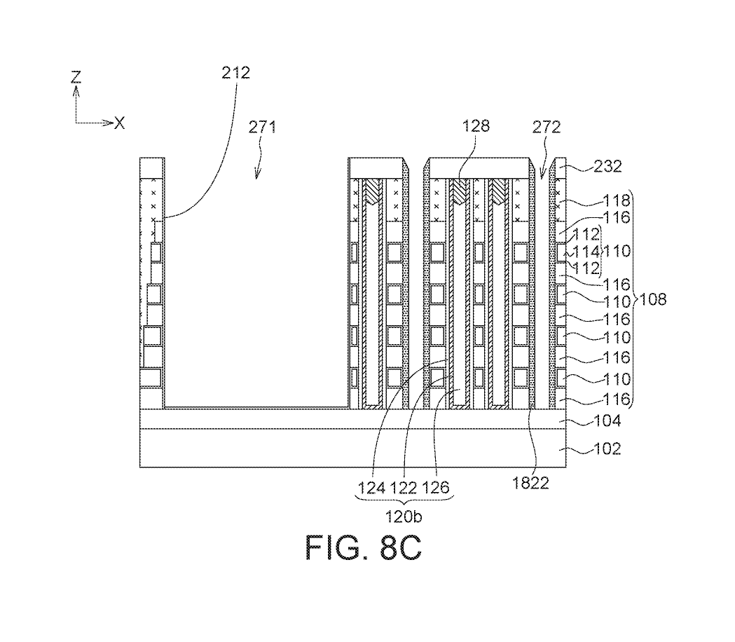

As shown in FIGS. 8A-8C, a conductive material is filled into remaining portions of spaces produced by removing the sacrificial layers 210. The conductive material may be tungsten (W). As such, the stacks 108 as shown in FIGS. 1A-1C are formed. In addition, unneeded portions of the high-k dielectric material are removed. That is, portions of the high-k dielectric material which is in the first openings 271 and on top of the interlayer dielectric layer 232 are removed. Then, insulating liner layers 1822 may be formed in the second openings 272, respectively, using an insulating material. For example, the insulating material may be an oxide material.

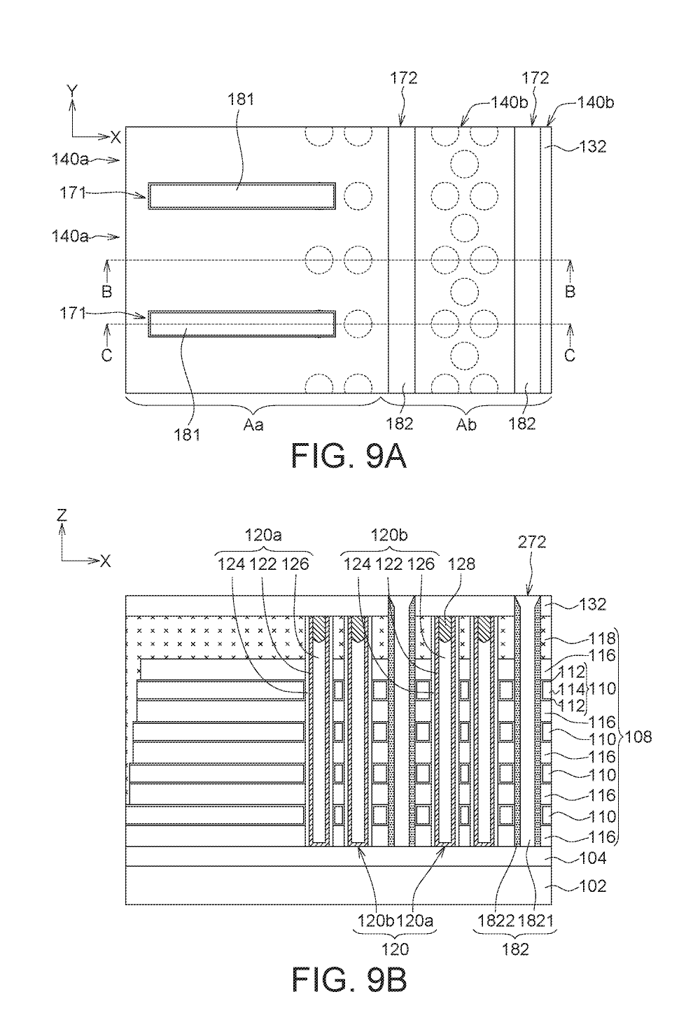

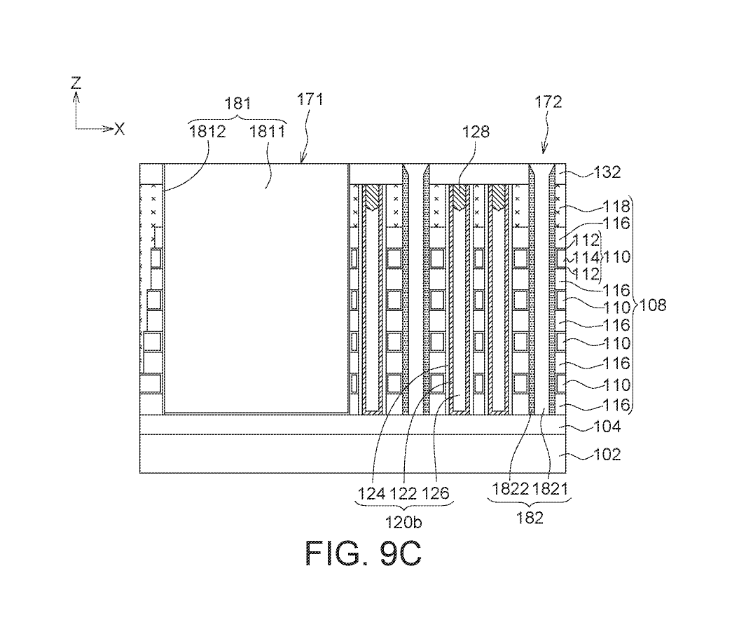

As shown in FIGS. 9A-9C, the conductive material is filled into the first openings 271 and the second openings 272. As such, conductive center portions 1821 are formed and isolated from the conductive layers 110 by the insulating liner layers 1822. The conductive material may be tungsten (W). Thereby, the first conductive structures 181 each comprising a high-k dielectric layer 1812 and a conductive filling portion 1811 are formed in the first predetermined trench positions 251. The second conductive structures 182 each comprising an insulating liner layer 1822 and a conductive center portion 1821 are formed in the second predetermined trench positions 252. In this way, each of the first conductive structures 181 extends along the first direction (such as the X-direction in the drawings), each of the second conductive structure 182 extends along the second direction (such as the Y-direction in the drawings).

Thereafter, other processes typically used for manufacturing a semiconductor structure, such as BEOL processes, may be carried out. For example, in the BEOL processes, word lines are defined using the conductive layers 110 disposed on the array area Ab, bit lines are defined using the conductive pads 128 disposed on the array area Ab, common source lines are defined using the conductive center portions 1821, and memory cells 130 are defined by cross points between the word lines and the channel layers 122. During the BEOL process, contacts (not shown) may be formed above the array area Ab, and no contact may be formed above the dummy area Aa.

In the method described above, since the first trenches are formed in the dummy area, and the extending direction of the first trenches is different from that of the second trenches in the array area, a stress in stacks having a high aspect ratio can be released by the first trenches, less stress may affect the structure on the array area and thereby the sloping of the stacks and the bending of the elements can be prevented. Furthermore, a dislocation of contacts formed in the BEOL processes due to the sloping of the stacks can be prevented. While the forgoing examples are illustrated using a 3-D vertical channel NAND memory structure and a method applying a process using sacrificial layers, the embodiments are not limited thereto. The concepts described here can be applied to other methods for manufacturing semiconductor structures in which stacks having a high aspect ratio are formed and the semiconductor structures manufactured by the methods.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a substrate, wherein the substrates comprises a dummy area and an array area adjacent to the dummy area;
a plurality of sub-dummy structures disposed on the dummy area, the sub-dummy structures separated from each other by a plurality of first trenches, wherein each of the first trenches extends along a first direction;
a plurality of sub-array structures disposed on the array area, the sub-array structures separated from each other by a plurality of second trenches, wherein each of the second trenches extends along a second direction;
a three-dimensional array of memory cells, wherein the memory cells comprise a plurality of cell groups disposed in the sub-array structures, respectively; and
a plurality of first conductive structures and a plurality of second conductive structures disposed in the first trenches and the second trenches respectively, wherein each of the first conductive structures extends along the first direction, each of the second conductive structure extends along the second direction, and the first direction is different from the second direction.

2. The semiconductor structure according to claim 1, wherein the first direction is perpendicular to the second direction.

3. The semiconductor structure according to claim 1, further comprising:
a plurality of first active structures, disposed on the dummy area; and
a plurality of second active structures, disposed on the array area;
wherein the first active structures have a first density in the dummy area, the second active structures have a second density in the array area, and the first density is smaller than the second density.

4. The semiconductor structure according to claim 1, wherein each of the first conductive structures comprises a conductive filling portion and a high-k dielectric layer surrounding the conductive filling portion.

5. The semiconductor structure according to claim 1, wherein each of the second conductive structures comprises a conductive center portion and an insulating liner layer surrounding the conductive center portion.

6. The semiconductor structure according to claim 1, wherein each of the sub-array structures respectively comprises:
a stack comprising alternately stacked conductive layers and insulating layers; and
one or more active structures penetrating through the stack, each of the one or more active structures comprising:
a channel layer; and
a memory layer disposed between the channel layer and the stack;
wherein the memory cells in the cell group disposed in each of the sub-array structures are defined by cross points between the conductive layers of the stack and the one or more active structures.

7. The semiconductor structure according to claim 6, wherein each of conductive layers comprises two high-k dielectric layers and a conductive core layer disposed therebetween.

8. The semiconductor structure according to claim 6, wherein each of the sub-array structures further comprises:
one or more conductive pads coupled to the one or more active structures, respectively.

9. The semiconductor structure according to claim 8, wherein the conductive layers of the sub-array structures are configured for word lines, the conductive pads of the sub-array structures are configured for bit lines, and the conductive center portion is configured for a common source line.

10. The semiconductor structure according to claim 6, wherein the each of the sub-array structures further comprises:
an interlayer dielectric layer disposed on the stack.

11. A method for manufacturing a semiconductor structure, comprising:
providing an initial structure, wherein the initial structure comprises a substrate and a preliminary array structure formed on the substrate, the substrate comprises a dummy area and an array area, the preliminary array structure comprises a stack and a plurality of active structures penetrating through the stack, and each of the active structures comprises a channel layer and a memory layer formed between the channel layer and the stack;
forming a plurality of first trenches extending along a first direction at first predetermined trench positions in the preliminary array structure for separating the preliminary array structure on the dummy area into a plurality of sub-dummy structures;
forming a plurality of second trenches extending along a second direction at second predetermined trench positions in the preliminary array structure for separating the preliminary array structure on the array area into a plurality of sub-array structures;
forming a plurality of first conductive structures and a plurality of second conductive structures in the first trenches and the second trenches respectively, wherein each of the first conductive structures extends along the first direction, each of the second conductive structure extends along the second direction, and the first direction is different from the second direction.

12. The semiconductor structure according to claim 11, wherein the first direction is perpendicular to the second direction.

13. The method according to claim 11, wherein forming the first conductive structures comprises:
forming a plurality of first openings in the first predetermined trench positions;
forming a high-k dielectric layer in each of the first openings; and
forming a conductive filling portion in each of the first openings.

14. The method according to claim 11, wherein forming the second conductive structures comprises:
forming a plurality of second openings in the second predetermined trench positions;
forming an insulating liner layer in each of the second openings; and
forming a conductive center portion in each of the second openings.

15. The method according to claim 14, wherein the insulating liner layer is formed of an oxide material.

16. The method according to claim 14, wherein the stack comprises alternately stacked sacrificial layers and insulating layers.

17. The method according to claim 16, further comprising:
replacing the sacrificial layers with conductive layers, comprising:
removing the sacrificial layers through the first openings and the second openings;
forming high-k dielectric layers on top sides and bottom sides of the insulating layers; and
filling a conductive material into remaining portions of spaces produced by removing the sacrificial layers.

18. The method according to claim 17, wherein the preliminary array structure further comprises:
a plurality of conductive pads coupled to the active structures, respectively.

19. The method according to claim 18, wherein the conductive layers of the sub-array structures are configured for word lines, the conductive pads of the sub-array structures are configured for bit lines, and the conductive center portion is configured for a common source line.

20. The method according to claim 16, wherein the preliminary array structure further comprises:
an interlayer dielectric layer formed on the stack.
